(19) United States
(12) Patent Application Publication
(10) Pub. No.: US 2025/0244398 A1
(43) Pub. Date: Jul. 31, 2025

(54) METHOD OF GENERATING ESTIMATION EQUATION FOR FULL CHARGE CAPACITY OF BATTERY OF ELECTRIC VEHICLE AFTER DEGRADATION

(71) Applicant: TOYOTA JIDOSHA KABUSHIKI KAISHA, Aichi (JP)

(72) Inventors: Kumiko NODA, Nagoya-shi (JP); Kouichi YOKOYAMA, Toyota-shi (JP)

(21) Appl. No.: 19/011,603

(22) Filed: Jan. 7, 2025

(30) Foreign Application Priority Data
Jan. 11, 2024 (JP) 2024-002498

(51) Int. Cl. G01R 31/392; B60L 58/16; G01R 31/367; G01R 31/374

(52) U.S. Cl. CPC G01R 31/392; B60L 58/16; G01R 31/367; G01R 31/374

(57) ABSTRACT

A method of generating an estimate equation for a full charge capacity of a battery of an electric vehicle after degradation is provided, the method may include the following processes. Preparing a first and a second estimate equations, the first estimate equation evaluates a first estimate value for the full charge capacity of the battery after degradation, the second estimate equation evaluates a second estimate value for the full charge capacity of the battery after degradation. The first estimate equation includes predetermined coefficients and first battery variables related to a condition of the battery, and the second estimate equation includes undetermined coefficients and second battery variables related to the condition of the battery. Collecting actual result data of the first and second battery variables from L electric vehicles. Specifying the undetermined coefficients using the collected actual data.

### REFERENCE TO RELATED APPLICATIONS

This application claims priority from Japanese Patent Application No. 2024-002498 filed on Jan. 11, 2024. The entire contents of the priority application are incorporated herein by reference.

### TECHNICAL FIELD

The art disclosed herein relates to a method for generating an estimate equation for estimating a full charge capacity of an electric vehicle battery after degradation.

### BACKGROUND ART

The full charge capacity of a battery used for a long period of time decreases from the full charge capacity at the start of use (initial full charge capacity) due to deterioration. Even if the battery is left unused for a long period of time, the full charge capacity will be lower than the initial full charge capacity due to degradation. This specification refers to the full charge capacity of a battery after a specified period of time as “full charge capacity after degradation”. An example of a technique for estimating the post-degradation full charge capacity is described in Japanese Patent Application Publication No. 2020-042036. The method in Japanese Patent Application Publication No. 2020-042036 estimates the full charge capacity after degradation using charge and discharge history of the battery.

### SUMMARY

This specification provides a technique for estimating a full charge capacity after degradation of a battery with higher accuracy than before. In this specification, the full charge capacity after degradation is expressed with a percentage when the initial full charge capacity is 100 [%].

A method of generating an estimate equation disclosed herein has the following seven steps.

(Step 1) Preparing a first estimate equation which evaluates a first estimate value for a full charge capacity of a battery after degradation and a second estimate equation which evaluates a second estimate value for the full charge capacity of the battery after degradation, the first estimate equation including predetermined coefficients and first battery variables related to a condition of the battery, and the second estimate equation including undetermined coefficients and second battery variables related to the condition of the battery. Specific structures of the first and second estimate equations are shown in “Detailed Description of Invention”.

(Step 2) Collecting actual result data of the first and second battery variables from L electric vehicles. (Step 3) Evaluating K first estimate values by assigning K actual result data related to the first battery variables among L actual result data into the first estimate equation. (Step 4) Specifying the undetermined coefficients by a multiple regression analysis using K second estimate equations into which the K first estimate values and the K actual result data related to the second battery variables among the L actual result data are assigned. (Step 5) Evaluating (L-K) second estimate values by assigning (L-K) actual result data related to the second battery variables among the L actual result data into the second estimate equation including the specified undetermined coefficients and of evaluating new (L-K) first estimate values by assigning (L-K) actual result data related to the first battery variables among the L actual result data into the first estimate equation. (Step 6) Correcting the specified undetermined coefficients so as to have a strong correlation between the (L-K) new first estimate values and the (L-K) second estimate values both evaluated by the fifth step. (Step 7) Evaluating the second estimate equation including the second battery variables and the specified and corrected undetermined coefficients as the estimate equation for the full charge capacity of the battery after degradation.

The first and second battery variables related to the battery status include non-use time and a quantity of applied electricity (applied electric quantity) for each temperature section when a battery temperature is sectioned into multiple temperature sections.

The method of generating an estimate equation disclosed herein employs battery variables defined for each battery temperature section, so that the full charge capacity after degradation can be estimated with high accuracy. In addition, K actual result data among the L actual result data are used to specify undetermined coefficients, and the remaining (L-K) actual result data are used to correct the specified undetermined coefficients. This also contributes to estimating the full charge capacity after degradation with high accuracy.

Details of the art disclosed herein and further improvements are described in “EMBODIMENT” below.

### BRIEF DESCRIPTION OF THE DRAWING

FIG. 1 shows a flowchart of a procedure for generating an estimate equation.

FIG. 2 shows an example of non-use time for each temperature section.

FIG. 3 shows a diagram for explaining a function y1 (X1, Z1).

FIG. 4 shows an example of the non-use time of a vehicle Ain each temperature section.

FIG. 5 shows an example of a battery non-use time x1ᵢ in each traveling section.

FIG. 6 shows an example of an applied electric quantity in each temperature section.

FIG. 7 shows a diagram for explaining a function y2 (X2, Z2).

FIG. 8 shows an example of a travel time of the vehicle A in each temperature section.

FIG. 9 shows an example of an applied electric quantity x2; in each temperature section.

FIG. 10 shows an example of small electric power charge time in each temperature section.

FIG. 11 shows an example of a correlation between first and second estimate values.

FIG. 12 shows an example of a correlation between objective variables and the second estimate values.

FIG. 13 shows an example of a result of repeated optimization of the undetermined coefficients.

### DETAILED DESCRIPTION

### Embodiment

As mentioned earlier, in this specification, the full charge capacity after degradation is expressed as a percentage relative to the initial full charge capacity. In other words, the initial full charge capacity is 100.

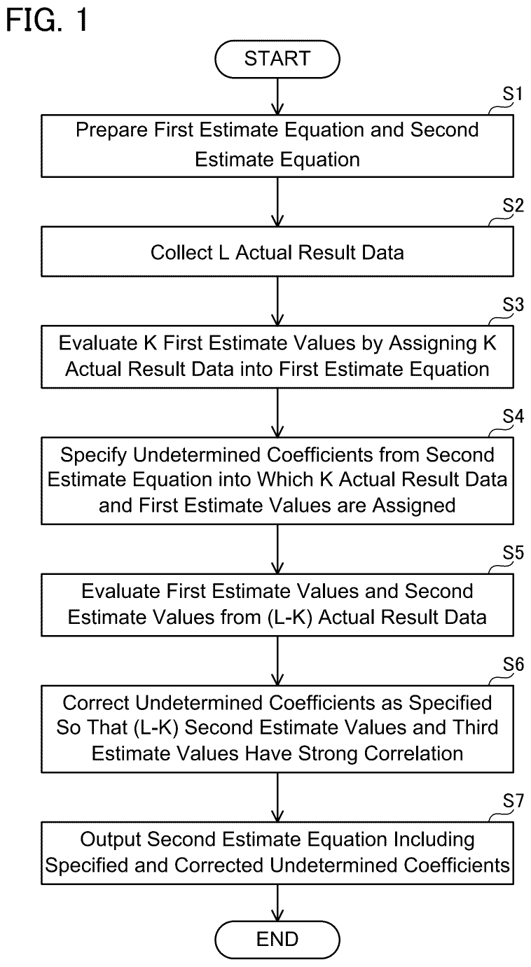

A method of generating an estimate equation disclosed herein comprises seven steps. FIG. 1 shows a flowchart of the procedure of the method of generating the estimate equation. Each step will be specifically described in detail.

(Step 1) In the first step, preparing first and second estimate equations for calculating estimate values for a full charge capacity after degradation (Step S1). The first estimate equation includes predetermined coefficients and first battery variables related to the condition of the battery. The estimate value of the full charge capacity after degradation obtained by the first estimate equation will be referred to as a first estimate value. The second estimate equation includes undetermined coefficients and second battery variables related to the condition of the battery. The estimate equation for the full charge capacity after degradation obtained by the second estimate equation will be referred to as a second estimate value.

The ultimate objective of the method for generating the estimate equation in the present embodiment is to collect measurements (i.e., actual result data) corresponding to the first and second battery variables from multiple electric vehicles actually used by user(s), and to specify and optimize the undetermined coefficients using those actual result data and the first estimate equation. By obtaining the optimized values of the undetermined coefficients, the second estimate equation can estimate the full charge capacity after degradation with high accuracy. The second estimate equation including the specified and optimized undetermined coefficients is the estimate equation to be sought.

The first estimate equation is given by (Equation 1) below. The “coefficients” in the present embodiment may include constants.

$$γ = 100 - \sqrt{( {( 100 - y 1 ( x 1 , z 1 ) )}^{2} + {( 100 - y 2 ( x 2 , z 2 ) )}^{2}} \qquad ( Eq . 1 )$$

In (Equation 1), y on the left side is the first estimate value. “100” on the right side means the initial full charge capacity.

The first battery variable z1 indicates one of temperature sections obtained by dividing a temperature range of the battery when the battery is not used into a plurality of temperature sections. The first battery variable x1 indicates a time for which the battery is not used at a temperature section z1. In the following, a time for which the battery is not used may simply be referred to as a non-use time. The function y1 (x1, z1) on the right side represents an estimate value of the full charge capacity after degradation due to the non-use time. The function y1 (x1, z1) includes pre-specified coefficients (i.e., predetermined coefficients), and the estimate value can be obtained by assigning the first battery variables x1 and z1. The predetermined coefficients will be described below.

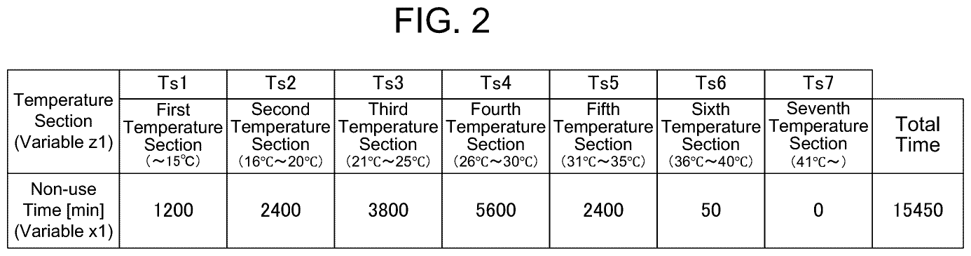

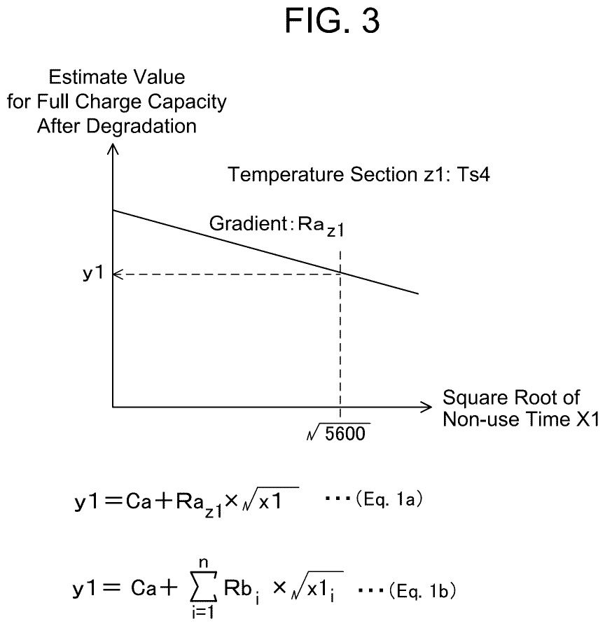

An example of temperature sections and non-use time is shown in FIG. 2. In the example in FIG. 2, there are seven temperature sections (Ts1-Ts7). The function y1 (x1, z1) is also shown in FIG. 3. The full charge capacity after degradation decreases according to the non-use time. The function y1 (x1, z1) is a linear function proportional to the square root of non-use time x1. Its gradient Ra takes a negative value. (Equation 1a) in FIG. 3 corresponds to the graph in FIG. 3. The constants Ca and gradient Ra have been determined in advance by experiment/simulation/analysis, etc. The fact that y1 is proportional to the square root of non-use time x1 is also a finding which was obtained by experiment and analysis. The constant Ca and the gradient Ra are the predetermined coefficients. An example of the constant Ca is 100. In the example in FIG. 2, a temperature at which the battery may be is sectioned into seven sections. Hence, a first battery variable x1 (non-use time x1) is assigned to each of the seven temperature sections.

The estimate value y1 due to the non-use time is obtained by (Equation 1b) in FIG. 3. In (Equation 1b), “n” means the number of temperature sections when the battery is not used. In the example in FIG. 1, n=7. Battery characteristic values obtained through experiments are used for the gradient Rb in (Equation 1b).

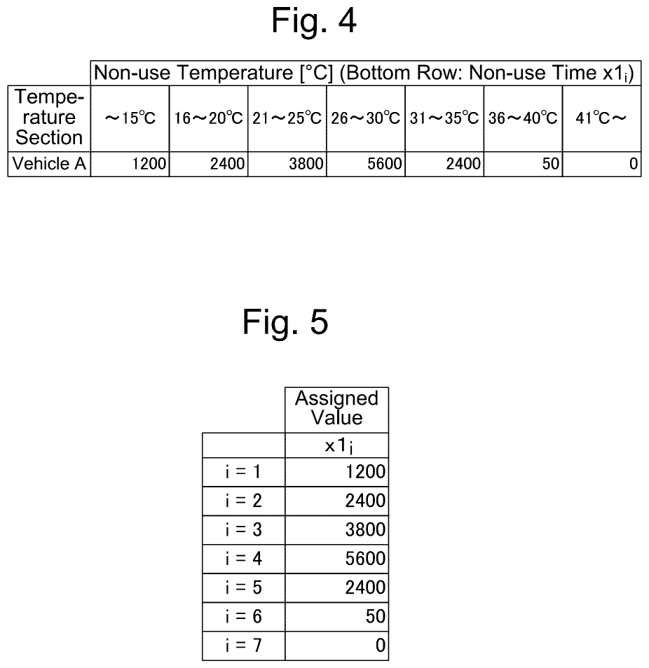

How to evaluate the non-use time x1ᵢ in (Equation 1b) will be described. The subscript “i” means i-th temperature section. In other words, “x1ᵢ ” means the battery non-use time in the i-th temperature section. The value of the battery non-use time recorded for each temperature section is used as it is as “x1ᵢ ”. An example of “x1ᵢ” is shown in FIGS. 4 and 5. FIG. 4 shows an example of the battery non-use time of a vehicle A in each temperature section. For example, the battery non-use time x1₂ for vehicle A in a temperature section “16-20° C.” (second temperature section) is “2400”. FIG. 5 shows an example of the battery non-use time “x1ᵢ” for each “i”. The battery non-use time x1 for each temperature section in FIG. 4 is assigned in each row of FIG. 5. In the following, “battery non-use time” may be simply referred to as “non-use time”.

The function y2 (x2, z2) on the right side of (Equation 1) will be described. The first battery variable z2 represents one of temperature sections obtained by dividing a temperature the battery may be at when the electric vehicle is traveling into a plurality of temperature sections. The temperature section of the first battery variable z2 may be the same as or different from the previous first battery variable z1. The first battery variable x2 represents an electric quantity flowing into and out of the battery at a temperature section z2. Hereafter, the quantity of electricity entering and leaving the battery will be referred to as an applied electric quantity. The function y2 (x2, z2) represents an estimate value of the full charge capacity after degradation due to the applied electric quantity during traveling. The function y2 (x2, z2) contains pre-specified coefficients (i.e., predetermined coefficients), and the estimate value can be obtained by assigning the first battery variables x2 and z2. The predetermined coefficients will described below.

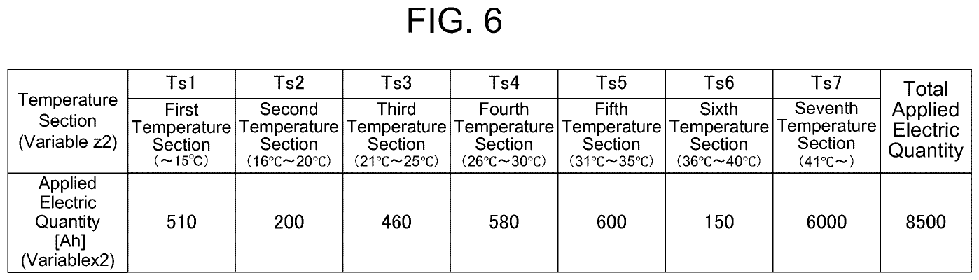

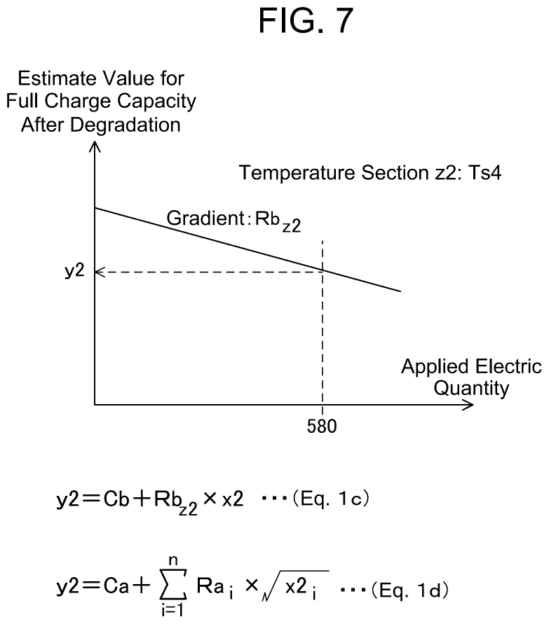

An example of temperature sections and applied electrical quantities is shown in FIG. 6. In this example, the battery temperature sections are the same as in FIG. 2 and are sectioned into seven (Ts1-Ts7). The function y2 (x2, z2) is shown in FIG. 7. The function y2 (x2, z2) is a linear function proportional to the applied electric quantity x2. Its gradient Rb takes a negative value. In other words, the full charge capacity after degradation becomes smaller as the applied electric quantity increases. (Equation 1c) in FIG. 7 corresponds to the graph in FIG. 7. The constant Cb and gradient Rb have been determined in advance by experiment/simulation/analysis, etc. The fact that y2 is proportional to the applied electric quantity x2 is also a finding obtained by experiment and analysis. The constant Cb and gradient Rb are predetermined coefficients. In the example in FIG. 6, a temperature at which the battery may be is sectioned into seven sections. Hence, the applied electric quantity x2 (first battery variable x2) is assigned to each of the seven temperature sections.

The estimate value y2 due to the applied electric quantity is obtained by (Equation 1d) in FIG. 7. In (Equation 1d), “n” means the number of temperature sections during traveling. In the example in FIG. 6, n=7. An example of the constant Ca in (Equation 1d) is 100. Battery characteristic values obtained through experiments are used for the gradient Ra in (Equation 1d).

How to evaluate the applied electric quantity x2; in (Equation 1d) will be described. The subscript “i” means the i-th temperature section. In other words, “x2ᵢ” means the applied electric quantity in the i-th temperature section. The applied electric quantity x2; is obtained by the following two steps.

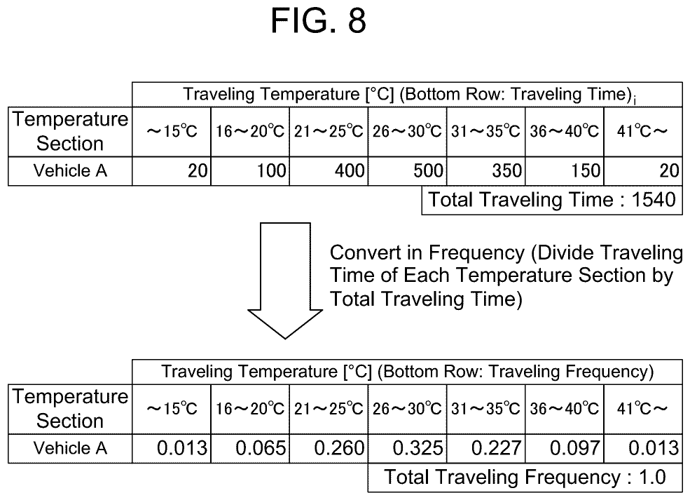

(Step 1) Measuring a traveling time for each temperature section when the vehicle is traveling in frequency. The upper row of FIG. 8 shows an example of the traveling time of vehicle A in each temperature section. For example, the traveling time of vehicle A in the temperature section “16-20° C.” (temperature section 2) is “100”. In the example in FIG. 8, a total time of traveling is 1540. The traveling time for each temperature section divided by the total traveling time is the traveling time converted in frequency, i.e., traveling frequency. The bottom row of FIG. 8 shows the traveling frequency of each temperature section. The sum of the traveling frequency for all the temperature sections is 1.0.

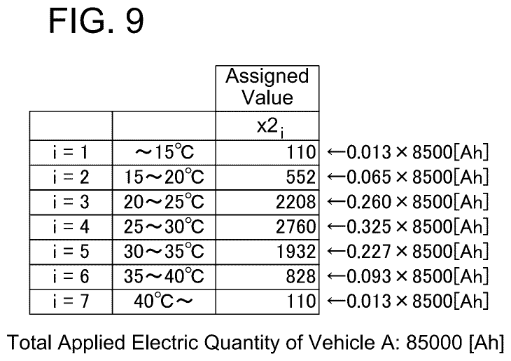

(Step 2) Multiplying the total applied electricity of vehicle A by the traveling frequency of each temperature section. FIG. 9 shows an example of the applied electric quantity x2 for each temperature section obtained in Step 2. For example, the applied electric quantity x2₅ in the fifth temperature section (i=5) is x2₅=0.227 (traveling frequency in the fifth temperature section)×8500 (total applied electric quantity)=1932.

(Equation 1) is an equation for obtaining the first estimate value y of the full charge capacity after degradation from the estimate value y1 due to the battery non-use time and the estimate value y2 due to the applied electric quantity. (Equation 1) includes predetermined coefficients and does not include any undetermined coefficients. By assigning the actual result data of the battery non-use time (first battery variable x1) and applied electric quantity (first battery variable x2) for each temperature section into (Equation 1), the first estimate value y is evaluated.

The second estimate equation is given by (Equation 2) as below.

$$Qdeg = 100 - ( Dpark + Dlow + Dhigh + Drun ) \qquad ( Eq . 2 )$$

Qdeg on the left side of (Equation 2) also represents an estimate value of the full charge capacity after degradation. Qdeg in (Equation 2) corresponds to the second estimate value.

Batteries mounted in electric vehicles degrade under the influence of a variety of variables related to the conditions of the electric vehicle and the battery. The following four factors are main factors affecting battery degradation. (1) Dpark: a non-use degradation quantity which indicates a degradation quantity of the battery caused by a time for which the battery is not use (battery non-use time). (2) Dlow: a small-electric-power-charge degradation quantity which indicates a degradation quantity of the battery when the battery is charged with electric power smaller than an electric power threshold. (3) Dhigh: a high-electric-power-charge degradation quantity which indicates a degradation quantity of the battery when the battery is charged with electric power larger than the electric power threshold. (4) Drun: a traveling degradation quantity which indicates a degradation quantity of the battery when the electric vehicle is traveling. The power threshold that distinguishes between the small electric power charge and the high electric power charge is set at several tens of kilowatts (e.g., 20 kilowatts). The power threshold is predetermined and stored in a controller of the electric vehicle.

(Equation 1) means that a decrease in the full charge capacity due to degradation is represented by the sum of the non-use degradation quantity Dpark, the small-electric-power-charge degradation quantity Dlow, the high-electric-power-charge degradation quantity Dhigh, and the traveling degradation quantity Drun. The estimation method disclosed herein estimates a total degradation quantity by evaluating the four main factors affecting degradation (Dpark, Dlow, Dhigh, and Drun) individually and adding them together. Since (Equation 2) estimates the degradation quantity for each degradation factor, it can accurately estimate the full charge capacity after degradation. (Equation 2) includes a plurality of battery variables. The battery variables included in (Equation 2) will be referred to as the second battery variables and will be distinguished from the first battery variables included in (Equation 1).

The non-use degradation quantity Dpark, will be described in detail. The non-use degradation quantity Dpark can be estimated by the following equation (Equation 2a).

$$Dpark = a \sqrt{{\sum }_{i = 1}^{n} {r}_{i}^{2}} ( {X}_{i} + C ) + b \sqrt{Y 1} \qquad ( Eq . 2 a )$$

Meanings of the symbols in (Equation 2a) are as follows.
a, b: the undetermined coefficients
Xᵢ: one of the second battery variables, Xᵢ indicating a time for which the battery is not used (non-use time) at a temperature section i which is one of n temperature sections when a temperature range of the battery is sectioned into n temperature sections;
rᵢ: one of the undetermined coefficients, rᵢ indicating contribution to degradation due to time for which the battery is not used at the temperature section i;
C: one of the second battery variables, C indicating a time from dispatch to arrival to a user of the electric vehicle;
Y1: one of the second battery variables, Y1 indicating a time for which a remaining level of the battery is equal or more than 80% of an initial full charge capacity while the battery is not used (total high electric power charge time);

The undetermined coefficients a, b, and rᵢ are determined from the first estimate equation and actual result data from multiple electric vehicles. A procedure for determining the undetermined coefficients will be described later.

The time C from dispatch to arrival to the user of the electric vehicle is uniquely determined when the electric vehicle arrives the user. In other words, C is a predetermined constant. The second battery variables, i.e., the non-use time Xᵢ of each temperature section, and the total high electric power charge time Y1, are periodically measured and accumulated by the controller of the electric vehicle. The accumulated values correspond to the actual result data of the battery variables.

The small electric power charge degradation amount Dlow is explained in detail. The small-electric-power-charge degradation quantity Dlow can be estimated by the following equation (Equation 2b).

$$Dlow = {c}_{k} {\sum }_{i = 1}^{n} {ra}_{i} ( {Tempa}_{i} ) {\sum }_{k = 1}^{m} \sqrt{{Z}_{k}} \qquad ( Eq . 2 b )$$

Meanings of the symbols in (Equation 2b) are as follows.
cₖ: one of the undetermined coefficients for an electric quantity section k which is one of m sections when a range of electric quantity charged by one time of small-electric-power-charge is sectioned into m sections;
Tempaᵢ: one of the second battery variables, Tempaᵢ indicating a value (times of small electric power charge) obtained by dividing a time spent for small-electric-power-charge at the temperature section i by a total time of the small-electric-power-charge, in which the temperature section i is one of the n temperature sections when the temperature range of the battery is sectioned into n temperature sections;
raᵢ: one of the undetermined coefficients, raᵢ indicating contribution to degradation due to use of the battery at the temperature section i;
Zₖ: one of the second battery variables, Zₖ indicating the number of times of charge (number of times of small electric power charge) at the electric quantity section k which is one of m sections when the range of electric quantity charged by one time of small-electric-power-charge is sectioned into m sections.

The undetermined coefficient raᵢ means a coefficient that converts battery use per unit of time into degradation quantity. The “battery use” means that the flow of electric current into and out of the battery. The undetermined coefficient cₖ is optimized from actual result data on the usage of the multiple electric vehicles used by users. The undetermined coefficients cₖ and raᵢ are also determined from the first estimate equation and the actual result data of the multiple electric vehicles. A procedure for determining the undetermined coefficients will be explained later.

The second battery variable Tempaᵢ, which represents the small electric power charge time for each temperature section, and the second battery variable Zₖ, which represents the number of times of small electric power charge, are periodically measured and accumulated by the controller of the electric vehicle. The accumulated values correspond to the actual result data of the second battery variables.

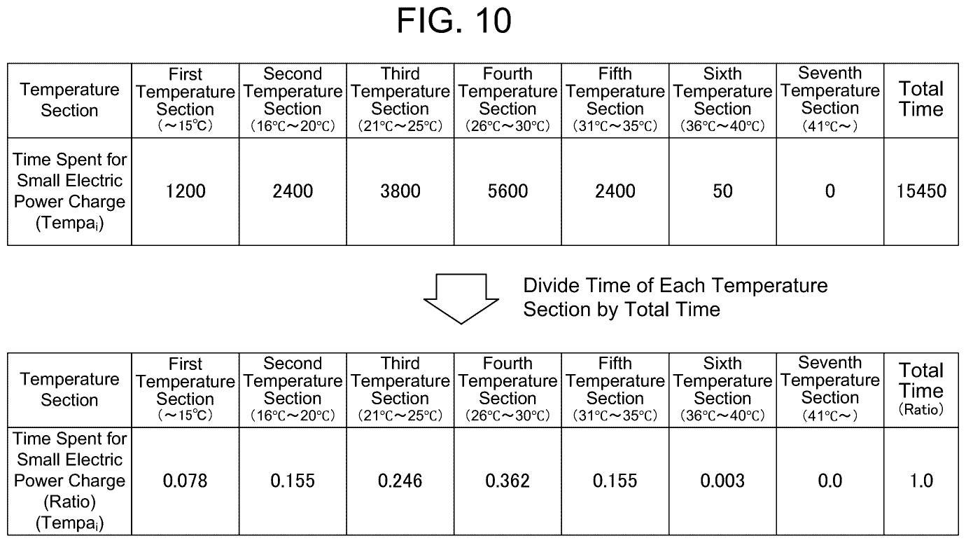

An example of the small electric power charge time Tempaᵢ for each temperature section is shown in FIG. 10. In the example in FIG. 10, the battery temperature is sectioned into seven temperature sections. That is, n=7 in (Equation 2b). The upper row of FIG. 10 shows the small electric power charge time for each temperature section. The electric vehicle is equipped with a temperature sensor configured to measure a temperature of the battery, and the controller accumulates and stores each of the data in the upper row in FIG. 10 from the temperature sensor measurements and the time required for the small electric power charge. The rightmost column of the upper row in FIG. 10 shows the total time required for the small electric power charge. In the lower table in FIG. 10, values obtained by dividing the charge time for each temperature section by the total time are assigned. The values in the lower table in FIG. 10 are an example of the actual result data for Tempaᵢ in (Equation 2b).

The high-electric-power-charge degradation quantity Dhigh will be explained in detail. The high-electric-power-charge degradation quantity Dhigh can be estimated by the following equation (Equation 2c).

$$Dhigh = {e}_{j} {\sum }_{i = 1}^{n} {ra}_{i} ( {Tempb}_{i} ) {\sum }_{j = 1}^{p} \sqrt{{W}_{j}} \qquad ( Eq . 2 c )$$

Meanings of the symbols in (Equation 2c) are as follows.
eⱼ: one of the undetermined coefficients for an electric quantity section j which is one of p electric quantity sections when a range of electric quantity charged by one time of high-electric-power-charge is sectioned into p sections;
Tempbᵢ: one of the second battery variables, Tempbᵢ indicating a value obtained by dividing a time spent for high-electric-power-charge at the temperature section i by a total time of high-electric-power-charge, wherein the temperature section i is one of the n temperature sections when the range of battery temperature is sectioned into n temperature sections;
raᵢ: one of the undetermined coefficients, raᵢ indicating contribution to degradation due to the use of the battery at the temperature section i;
Wⱼ: one of the second battery variables, Wⱼ indicating the number of times of charge (number of times of high-electric-power charge) at an electric quantity section j which is one of the p sections when the range of electric quantity charged by one time of high-electric-power-charge is sectioned into p sections.

The undetermined coefficient representing contribution raᵢ is identical to the undetermined coefficient used in (Equation 2b). The undetermined coefficients eₖ and raᵢ are also determined to optimal values based on the first estimate equation and the actual values of the multiple electric vehicles. A procedure for determining the undetermined coefficients will be explained later. The battery variable Tempbᵢ is the same as the battery variable Tempaᵢ in (Equation 2b).

The second battery variable Tempbᵢ, which represents the high electric power charge time for each battery temperature section, and the second battery variable Wₖ, which represents the number of times of high electric power charge, are periodically measured and accumulated by the controller of the electric vehicle. The accumulated values correspond to the actual result data of the second battery variables.

The traveling degradation quantity Drun will be specifically described. The traveling degradation quantity Drun can be estimated by the following equation (Equation 2d).

$$Drun = d {\sum }_{i = 1}^{n} {ra}_{i} ( {Tempc}_{i} ) \sqrt{{I}_{EV}} \qquad ( Eq . 2 d )$$

Meanings of the symbols in (Equation 2d) are as follows.
d: one of the undetermined coefficients;
Tempcᵢ: one of the second battery variables, Tempcᵢ indicating a value (traveling time) obtained by dividing a time for which the electric vehicle traveled at the temperature section i by a total time of traveling, wherein the temperature section i is one of the n temperature sections when the range of battery temperature is sectioned into n temperature sections;
raᵢ: one of the undetermined coefficients, raᵢ indicating contribution to degradation due to use of the battery at the temperature section i;
I_{EV}: one of the second battery variables, I_{EV} indicating a total electric quantity flowing and out of the battery while the electric vehicle traveled.

The second battery variable Tempcᵢ, which represents the traveling time for each battery temperature section, is the same as the second battery variable Tempaᵢ in (Equation 2b). The undetermined coefficient raᵢ is the same as the undetermined coefficient used in (Equation 2b). The undetermined coefficients d and raᵢ are determined to be optimal values from the first estimate equation and actual result data on the usage conditions of the multiple electric vehicles used by users.

The traveling time Tempcᵢ for each temperature section and the total electric quantity I_{EV} are periodically measured and accumulated by the controller of the electric vehicle. The accumulated values correspond to the actual result data of the second battery variables.

The first estimate equation (Equation 1, Equation 1a to Equation 1d) includes the first battery variables x1, x2, z1, z2 and the predetermined coefficients Ca, Cb, Raᵢ, Rbᵢ (i is an index indicating the temperature section). The predetermined coefficients Ca, Raᵢ determine a relation between the non-use time of the battery and the full charge capacity after degradation. The predetermined coefficients Cb, Rbᵢ determine a relation between the applied electric quantity and the full charge capacity after degradation. The predetermined coefficients of the first estimate equation have been specified in advance by experiment/simulation/theoretical analysis.

The second estimate equation (Eq.2) includes the second battery variables Xᵢ, C, Y1, Tempaᵢ, Zₖ, Tempbᵢ, Wⱼ, Tempcᵢ, and I_{EV}. The second estimate equation (Eq. 2) includes the undetermined coefficients a, b, rᵢ, cₖ, raᵢ, eᵢ, raᵢ, and d. In the following, the first and second battery variables will be collectively referred to as “battery variables”.

(Step 2) Collecting actual result data of the first and second battery variables from L electric vehicles (FIG. 1, Step S2). The number L is much greater than the number of undetermined coefficients. Each of the electric vehicles targeted by the method of generating the estimate equation is equipped with a communication device. The electric vehicles also periodically store measurements corresponding to battery variables. The measurements stored by the electric vehicle correspond to the actual result data of the battery variables. The electric vehicles periodically send the actual result data of the battery variables to a management center. A computer at the management center collects the actual result data of the battery variables from the L electric vehicles.

(Step 3) Evaluating K first estimate values by assigning K actual result data related to the first battery variables among L actual result data into the first estimate equation (Step S3).

(Step 4) Specifying the undetermined coefficients by a multiple regression analysis using K second estimate equations into which the K first estimate values and the K actual result data related to the second battery variables among the L actual result data are assigned (FIG. 1, Step S4). The actual result data of the first battery variables and the actual result data of the second battery variables in the actual result data of one electric vehicle both correspond to the full charge capacity after degradation of that electric vehicle. The first estimate value obtained by assigning the actual result data of the first battery variables into the first estimate equation should be equal to the left side of the second estimate equation (i.e., the second estimate value) when the actual result data of the second battery variables are input. In other words, the first estimate value can be assigned into the left side of the second estimate equation. In this case, the K second estimate equation in which the actual result data are assigned into the second battery variables on the right side of the second estimate equation can be regarded as a multiple regression equation in which the first estimate value on the left side is an objective variable and the undetermined coefficients are explanatory variables. Therefore, multiple regression analysis can be used to specify the undetermined coefficients from the K second estimate equations.

(Step 5) Evaluating (L-K) second estimate values by assigning (L-K) actual result data related to the second battery variables among the L actual result data into the second estimate equation including the specified undetermined coefficients and of evaluating new (L-K) first estimate values by assigning (L-K) actual result data related to the first battery variables among the L actual result data into the first estimate equation (FIG. 1, Step S5).

(Step 6) Correcting the specified undetermined coefficients so as to have a strong correlation between the (L-K) new first estimate values and the (L-K) second estimate values both evaluated by the fifth step. The (L-K) actual result data are not used to specify the undetermined coefficients. The computer corrects the coefficients using the (L-K) actual result data and the first estimate values corresponding to the (L-K) actual result data. The computer assigns the (L-K) actual result data related to the second battery variables into (Equation 2) to evaluate the second estimate values. The values specified in step S5 are used for the undetermined coefficients in (Equation 2). The computer also assigns the (L-K) actual result data related to the first battery variables into (Equation 1) to evaluate newly new first estimate values.

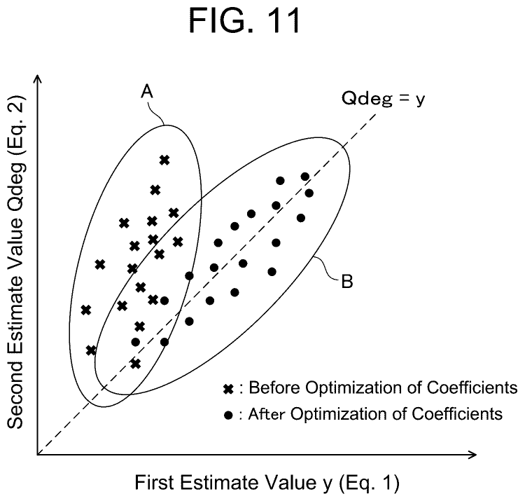

FIG. 11 shows an example of a correlation between the first estimate values and second estimate values. FIG. 11 plots pairs of first estimate values y and second estimate values Qdeg, calculated using (L-K) actual result data. Group A is a result of the pairs of estimate values when the coefficients before correction are used. The first and second estimate values should be equal. If the first and second estimate values are equal, the pairs of first and second estimate values would lie on a 45-degree line. Before correction (Group A), the specified undetermined coefficients are not accurate and the pairs of first and second corrected values are apart from the 45-degree line.

In the sixth step, the finalized undetermined coefficients are corrected so that the pairs of first and second corrected values are distributed along the 45-degree line. Group B in FIG. 11 represents distribution of the pairs of first and second estimate values when the corrected coefficients are used. Optimizing the specified undetermined coefficients by correction improves accuracy of (Equation 2).

(Step 7) Evaluating the second estimate equation including the second battery variables and the specified and corrected undetermined coefficients as the estimate equation for the full charge capacity of the battery after degradation. As mentioned above, by optimizing the coefficients (specified undetermined coefficients) using (L-K) actual result data and (Equation 1), a highly accurate estimate equation for the full charge capacity after degradation can be obtained.

Next, an example of optimization of the undetermined coefficients will be given. The first estimate equation (Equation 1) and the second estimate equation (Equation 2) are as described above (Step 1).

(Step 2) Collecting actual result data of the first and second battery variables from L electric vehicles. The first battery variables are x1, x2, z1, and z2 in (Equation 1). The battery non-use time is used as x1. One of temperature sections obtained by dividing a temperature range of the battery when the battery is not used into a plurality of temperature sections is used as z1. The total applied electric quantity is used as x2. One of temperature sections obtained by dividing a temperature when the electric vehicle is traveling into a plurality of temperature sections is used as z2. The second battery variables are Xᵢ, C, Y1, Tempaᵢ, Zₖ, Tempbᵢ, Wⱼ, Tempcᵢ, and I_{EV} in (Equation 2a), (Equation 2b), (Equation 2c), and (Equation 2d). The meanings of the symbols are as described above. The first and second battery variables are constantly measured and stored in each of the electric vehicles that are actually traveling.

(Step 3a) Evaluating L first estimate values y by assigning L first battery variables included in the L actual result data into the first estimate equation (Equation 1). For convenience of explanation, the L first estimate values y will be hereinafter referred to as L objective variables y.

(Step 3b) Dividing the L objective variables y into K training data and (L-K) test data. Selection of the training data and the test data may be random. The ratio of K to (L-K) is preferably 8:2.

Some initial values are defined for the undetermined coefficients a, b, rᵢ, cₖ, raᵢ, eⱼ, raᵢ, and d in (Equation 2a), (Equation 2b), (Equation 2c), and (Equation 2d).

(Step 4) Evaluating K second estimate values Qdeg by assigning the initial values of the undetermined coefficients and the K battery variables into the second estimate equation (Equation 2). The undetermined coefficients a, b, rᵢ, cₖ, raᵢ, eⱼ, raᵢ, and d are optimized so that an absolute value of the difference (|y−Qdeg|) between each of the K training data y and each of the K estimate values Qdeg is minimized. A genetic algorithm is suitable for algorithm used for the optimization.

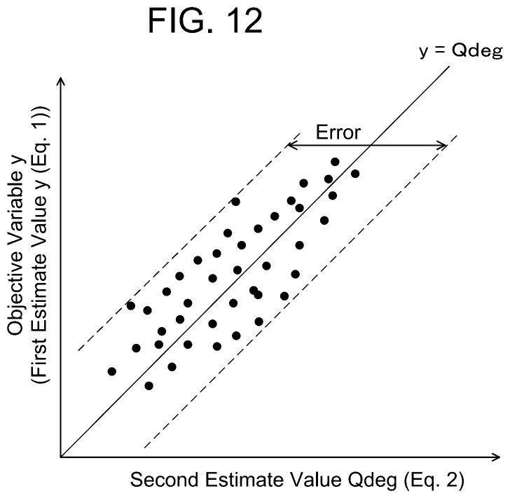

(Step 5) Verifying accuracy of the second estimate equation (Equation 2) (accuracy of the undetermined coefficients determined by optimization) using the (L-K) test data y. Specifically, the following processes are performed. (L-K) second estimate values Qdeg are evaluated by assigning (L-K) second battery variables into the second estimate equation after optimizing the undetermined coefficients. (L-K) pairs of the test data y and the second estimate Qdeg corresponding to each test data y (y, Qdeg) are plotted on a graph. An example of the plot is shown in FIG. 12. Average errors and maximum errors of the (L-K) pairs (y, Qdeg) are calculated.

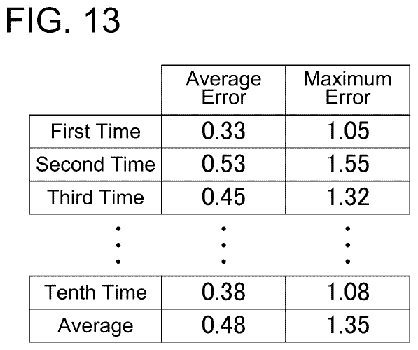

(Step 6) Repeating the processes from Steps 3b through 5, 10 times. An example of results (average errors and maximum errors) when the processes are repeated 10 times is shown in FIG. 13.

(Step 7) Adopting an average value of the average errors and an average value of the maximum errors when the processes from Step 3b to Step 5 are repeated 10 times as the accuracy of the second estimate equation.

Some points to be noted on the techniques described in the embodiment will be described. The structures of the equations introduced in the embodiment are based on findings from experiments/simulations/analysis, etc.

The method of generating an estimate equation disclosed herein may be performed by a computer and/or by a person.

While specific examples of the present disclosure have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present disclosure is not limited to the combinations described at the time the claims are filed. Further, the purpose of the examples illustrated by the present description or drawings is to satisfy multiple objectives simultaneously, and satisfying any one of those objectives gives technical utility to the present disclosure.

What is claimed is:

1. A method of generating an estimate equation for a full charge capacity of a battery of an electric vehicle after degradation, the method comprising:
a first step of preparing a first estimate equation which evaluates a first estimate value for the full charge capacity of the battery after degradation and a second estimate equation which evaluates a second estimate value for the full charge capacity of the battery after degradation, the first estimate equation including predetermined coefficients and first battery variables related to a condition of the battery, and the second estimate equation including undetermined coefficients and second battery variables related to the condition of the battery;
a second step of collecting actual result data of the first and second battery variables from L electric vehicles;
a third step of evaluating K first estimate values by assigning K actual result data related to the first battery variables among L actual result data into the first estimate equation;
a fourth step of specifying the undetermined coefficients by a multiple regression analysis using K second estimate equations into which the K first estimate values and the K actual result data related to the second battery variables among the L actual result data are assigned;
a fifth step of evaluating (L-K) second estimate values by assigning (L-K) actual result data related to the second battery variables among the L actual result data into the second estimate equation including the specified undetermined coefficients and of evaluating new (L-K) first estimate values by assigning (L-K) actual result data related to the first battery variables among the L actual result data into the first estimate equation;
a sixth step of correcting the specified undetermined coefficients so as to have a strong correlation between the (L-K) new first estimate values and the (L-K) second estimate values both evaluated by the fifth step; and
a seventh step of evaluating the second estimate equation including the second battery variables and the specified and corrected undetermined coefficients as the estimate equation for the full charge capacity of the battery after degradation,
wherein the first estimate equation is represented by following (Eq. 1);
$$γ = 100 - \sqrt{( {( 100 - y 1 ( x 1 , z 1 ) )}^{2} + {( 100 - y 2 ( x 2 , z 2 ) )}^{2}} \qquad ( Eq . 1 )$$
where:
y: the first estimate value for the full charge capacity of the battery after degradation;
y1(x1, z1): a function including predetermined coefficients, arguments x1, z1 being the first battery variables;
z1: one of the first battery variables, z1 indicating one of temperature sections obtained by dividing a temperature range of the battery when the battery is not used into a plurality of temperature sections;
x1: one of the first battery variables, x1 indicating a time for which the battery is not used at a temperature section z1;
y2(x2, z2): a function including the predetermined coefficients, arguments x2, z2 being the first battery variables;
z2: one of the first battery variables, z2 indicating one of temperature sections obtained by dividing a temperature at which the battery may be when the electric vehicle is traveling into a plurality of temperature sections;
x2: one of the first battery variables, x2 indicating an electric quantity flowing into and out of the battery at a temperature section z2;
the second estimate equation is represented by following (Eq. 2);
$$Qdeg = 100 - ( Dpark + Dlow + Dhigh + Drun ) \qquad ( Eq . 2 )$$
where:
Qdeg: the second estimate value for the full charge capacity of the battery after degradation;
Dpark: a non-use degradation quantity which indicates a degradation quantity of the battery caused by a time for which the battery is not used:
Dlow: a small-electric-power-charge degradation quantity which indicates a degradation quantity of the battery when the battery is charged with electric power smaller than an electric power threshold;
Dhigh: a high-electric-power-charge degradation quantity which indicates a degradation quantity of the battery when the battery is charged with electric power larger than the electric power threshold;
Drun: a traveling degradation quantity which indicates a degradation quantity of the battery when the electric vehicle is traveling;
Dpark is represented by following (Eq. 2a);
$$Dpark = a \sqrt{{\sum }_{i = 1}^{n} {r}_{i}^{2}} ( {X}_{i} + C ) + b \sqrt{Y 1} \qquad ( Eq . 2 a )$$
where:
a, b: the undetermined coefficients;
Xᵢ: one of the second battery variables, Xᵢ indicating a time for which the battery is not used at a temperature section i which is one of n temperature sections when a temperature range of the battery is sectioned into n temperature sections;
rᵢ: one of the undetermined coefficients, rᵢ indicating contribution to degradation due to time for which the battery is not used at the temperature section i;
C: one of the second battery variables, C indicating a time from dispatch to arrival to a sales destination of the electric vehicle;
Y1: one of the second battery variables, Y1 indicating a time for which a remaining level of the battery is equal or more than 80% of an initial full charge capacity while the battery is not used;
Dlow is represented by following (Eq. 2b);
$$Dlow = {c}_{k} {\sum }_{i = 1}^{n} {ra}_{i} ( {Tempa}_{i} ) {\sum }_{k = 1}^{m} \sqrt{{Z}_{k}} \qquad ( Eq . 2 b )$$
where:
cₖ: one of the undetermined coefficients for an electric quantity section k which is one of m sections when a range of electric quantity charged by one time of small-electric-power-charge is sectioned into m sections;
Tempaᵢ: one of the second battery variables, Tempaᵢ indicating a value obtained by dividing a time spent for small-electric-power-charge at the temperature section i by a total time of the small-electric-power-charge, in which the temperature section i is one of the n temperature sections when the temperature range of the battery is sectioned into n temperature sections;
raᵢ: one of the undetermined coefficients, raᵢ indicating contribution to degradation due to use of the battery at the temperature section i;
Zₖ: one of the second battery variables, Zₖ indicating the number of times of charge at the electric quantity section k which is one of m sections when the range of electric quantity charged by one time of small-electric-power-charge is sectioned into m sections;
Dhigh is represented by following (Eq. 2c);
$$Dhigh = {e}_{j} {\sum }_{i = 1}^{n} {ra}_{i} ( {Tempb}_{i} ) {\sum }_{j = 1}^{p} \sqrt{{W}_{j}} \qquad ( Eq . 2 c )$$
where:
eⱼ: one of the undetermined coefficients for an electric quantity section j which is one of p electric quantity sections when a range of electric quantity charged by one time of high-electric-power-charge is sectioned into p sections;
Tempbᵢ: one of the second battery variables, Tempbᵢ indicating a value obtained by dividing a time spent for high-electric-power-charge at the temperature section i by a total time of high-electric-power-charge, wherein the temperature section i is one of the n temperature sections when the range of battery temperature is sectioned into n temperature sections;
raᵢ: one of the undetermined coefficients, raᵢ indicating contribution to degradation due to the use of the battery at the temperature section i;
Wⱼ: one of the second battery variables, Wⱼ indicating the number of times of charge at an electric quantity section j which is one of the p sections when the range of electric quantity charged by one time of high-electric-power-charge is sectioned into p sections;
Drun is represented by following (Eq. 2d);
$$Drun = d {\sum }_{i = 1}^{n} {ra}_{i} ( {Tempc}_{i} ) \sqrt{{I}_{EV}} \qquad ( Eq . 2 d )$$
where:
d: one of the undetermined coefficients;
Tempcᵢ: one of the second battery variables, Tempcᵢ indicating a value obtained by dividing a time for which the electric vehicle traveled at the temperature section i by a total time of traveling, wherein the temperature section i is one of the n temperature sections when the range of battery temperature is sectioned into n temperature sections;
raᵢ: one of the undetermined coefficients, raᵢ indicating contribution to degradation due to use of the battery at the temperature section i;
I_{EV}: one of the second battery variables, I_{EV} indicating a total electric quantity flowing and out of the battery while the electric vehicle traveled.
